(19) United States
(12) Patent Application Publication
(10) Pub. No.: US 2024/0194625 A1
(43) Pub. Date: Jun. 13, 2024

(54) METAL PADS OVER TSV

(71) Applicant: ADEIA SEMICONDUCTOR BONDING TECHNOLOGIES INC., San Jose, CA (US)

(72) Inventors: Guilian Gao, San Jose, CA (US); Bongsub Lee, Santa Clara, CA (US); Gaius Gillman Fountain, JR., Youngsville, NC (US); Cyprian Emeka Uzoh, San Jose, CA (US); Laura Wills Mirkarimi, Sunol, CA (US); Belgacem Haba, Saratoga, CA (US); Rajesh Katkar, Milpitas, CA (US)

(21) Appl. No.: 18/582,312

(22) Filed: Feb. 20, 2024

Related U.S. Application Data
(63) Continuation of application No. 17/836,840, filed on Jun. 9, 2022, now Pat. No. 11,955,445.
Application No. 17/836,840 is a continuation of application No. 16/439,622, filed on Jun. 12, 2019, now Pat. No. 11,393,779.
(60) Provisional application No. 62/846,081, filed on May 10, 2019.
(60) Provisional application No. 62/684,505, filed on Jun. 13, 2018.

(51) Int. Cl. H01L 23/00; H01L 21/768; H01L 23/48; H01L 25/00; H01L 25/065

(52) U.S. Cl. CPC H01L 24/08; H01L 21/76898; H01L 23/481; H01L 24/03; H01L 24/05; H01L 24/06; H01L 24/09; H01L 24/80; H01L 25/0657; H01L 25/50; H01L 24/94; H01L 2224/05147; H01L 2224/05181; H01L 2224/05184; H01L 2224/08146; H01L 2224/80896

(57) ABSTRACT

Representative techniques and devices including process steps may be employed to mitigate the potential for delamination of bonded microelectronic substrates due to metal expansion at a bonding interface. For example, a metal pad having a larger diameter or surface area (e.g., oversized for the application) may be used when a contact pad is positioned over a TSV in one or both substrates.

### PRIORITY CLAIM AND CROSS-REFERENCE TO RELATED APPLICATION

This application is a continuation of U.S. application Ser. No. 17/836,840, filed Jun. 9, 2022, which is a continuation of U.S. application Ser. No. 16/439,622, filed Jun. 12, 2019, issued as U.S. Pat. No. 11,393,779, which claims the priority of U.S. Provisional Application No. 62/846,081, filed May 10, 2019 and U.S. Provisional Application No. 62/684,505, filed Jun. 13, 2018, the disclosures of each of which are hereby incorporated by reference in their entireties for all purposes.

### FIELD

The following description relates to integrated circuits (“ICs”). More particularly, the following description relates to manufacturing IC dies and wafers.

### BACKGROUND

Microelectronic elements often comprise a thin slab of a semiconductor material, such as silicon or gallium arsenide, commonly called a semiconductor wafer. A wafer can be formed to include multiple integrated chips or dies on a surface of the wafer and/or partly embedded within the wafer. Dies that are separated from a wafer are commonly provided as individual, prepackaged units. In some package designs, the die is mounted to a substrate or a chip carrier, which is in turn mounted on a circuit panel, such as a printed circuit board (PCB). For example, many dies are provided in packages suitable for surface mounting.

Packaged semiconductor dies can also be provided in “stacked” arrangements, wherein one package is provided, for example, on a circuit board or other carrier, and another package is mounted on top of the first package. These arrangements can allow a number of different dies or devices to be mounted within a single footprint on a circuit board and can further facilitate high-speed operation by providing a short interconnection between the packages. Often, this interconnect distance can be only slightly larger than the thickness of the die itself. For interconnection to be achieved within a stack of die packages, interconnection structures for mechanical and electrical connection may be provided on both sides (e.g., faces) of each die package (except for the topmost package).

Additionally, dies or wafers may be stacked in a three-dimensional arrangement as part of various microelectronic packaging schemes. This can include stacking a layer of one or more dies, devices, and/or wafers on a larger base die, device, wafer, substrate, or the like, stacking multiple dies or wafers in a vertical or horizontal arrangement, and various combinations of both.

Dies or wafers may be bonded in a stacked arrangement using various bonding techniques, including direct dielectric bonding, non-adhesive techniques, such as ZiBond® or a hybrid bonding technique, such as DBI®, both available from Invensas Bonding Technologies, Inc. (formerly Ziptronix, Inc.), an Xperi company. The bonding includes a spontaneous process that takes place at ambient conditions when two prepared surfaces are brought together (see for example, U.S. Pat. Nos. 6,864,585 and 7,485,968, which are incorporated herein in their entirety).

Respective mating surfaces of the bonded dies or wafers often include embedded conductive interconnect structures (which may be metal), or the like. In some examples, the bonding surfaces are arranged and aligned so that the conductive interconnect structures from the respective surfaces are joined during the bonding. The joined interconnect structures form continuous conductive interconnects (for signals, power, etc.) between the stacked dies or wafers.

There can be a variety of challenges to implementing stacked die and wafer arrangements. When bonding stacked dies using a direct bonding or hybrid bonding technique, it is usually desirable that the surfaces of the dies to be bonded be extremely flat, smooth, and clean. For instance, in general, the surfaces should have a very low variance in surface topology (i.e., nanometer scale variance), so that the surfaces can be closely mated to form a lasting bond.

Double-sided dies can be formed and prepared for stacking and bonding, where both sides of the dies will be bonded to other substrates or dies, such as with multiple die-to-die or die-to-wafer applications. Preparing both sides of the die includes finishing both surfaces to meet dielectric roughness specifications and metallic layer (e.g., copper, etc.) recess specifications. For instance, conductive interconnect structures at the bonding surfaces may be slightly recessed, just below the insulating material of the bonding surface. The amount of recess below the bonding surface may be determined by a dimensional tolerance, specification, or physical limitation of the device or application. The hybrid surface may be prepared for bonding with another die, wafer, or other substrate using a chemical mechanical polishing (CMP) process, or the like.

In general, when direct bonding surfaces containing a combination of a dielectric layer and one or more metal features (e.g., embedded conductive interconnect structures) are bonded together, the dielectric surfaces bond first at lower temperatures and the metal of the features expands afterwards, as the metal is heated during annealing. The expansion of the metal can cause the metal from both bonding surfaces to join into a unified conductive structure (metal-to-metal bond). While both the substrate and the metal are heated during annealing, the coefficient of thermal expansion (CTE) of the metal relative to the CTE of the substrate generally dictates that the metal expands much more than the substrate at a particular temperature (e.g., ˜300° C.). For instance, the CTE of copper is 16.7, while the CTE of fused silica is 0.55, and the CTE of silicon is 2.56.

In some cases, the greater expansion of the metal relative to the substrate can be problematic for direct bonding stacked dies or wafers. If a metal pad is positioned over a through-silicon via (TSV), the expansion of the TSV metal can contribute to the expansion of the pad metal. In some cases, the combined metal expansion can cause localized delamination of the bonding surfaces, as the expanding metal rises above the bonding surface. For instance, the expanded metal can separate the bonded dielectric surfaces of the stacked dies.

### BRIEF DESCRIPTION OF THE DRAWINGS

The detailed description is set forth with reference to the accompanying figures. In the figures, the left-most digit(s) of a reference number identifies the figure in which the reference number first appears. The use of the same reference numbers in different figures indicates similar or identical items.

For this discussion, the devices and systems illustrated in the figures are shown as having a multiplicity of components. Various implementations of devices and/or systems, as described herein, may include fewer components and remain within the scope of the disclosure. Alternatively, other implementations of devices and/or systems may include additional components, or various combinations of the described components, and remain within the scope of the disclosure.

FIG. 1A shows a cross-section of an example substrate with bonding pads and a TSV.

FIG. 1B shows a top view of the example substrate of FIG. 1A.

FIG. 2 shows a cross-section of two example bonded substrates with bonding pads and TSVs, and example resulting delamination.

FIG. 3A shows a cross-section of an example substrate with larger bonding pads positioned over the TSV, according to an embodiment.

FIG. 3B shows a top view of the example substrate of FIG. 3A, according to an embodiment.

FIG. 4 shows a cross-section of two example bonded substrates with larger bonding pads positioned over the TSV, according to an embodiment.

FIG. 5 shows a cross-section of an example substrate with a bonding pad positioned over a TSV, illustrating an example recess of the bonding pad.

FIG. 6 shows a cross-section of an example substrate with a larger bonding pad positioned over a TSV, illustrating an example recess of the bonding pad, according to an embodiment.

FIG. 7 shows a cross-section of two example bonded substrates with bonded pads having non-flat bonding surfaces, before and after annealing, according to an embodiment.

FIG. 8 shows a cross-section of an example substrate with a bonding pad positioned over the TSV, and with erosion or recessing of dielectric around the bonding pad, according to an embodiment.

FIGS. 9-13 show a cross-section of an example substrate with a bonding pad positioned over a TSV, illustrating an example backside process of the substrate, according to an embodiment.

FIG. 14 shows a cross-section of two example bonded substrates with TSVs and bonding pads, bonded front to back, according to an embodiment.

FIG. 15 shows a cross-section of two example bonded substrates with TSVs and bonding pads, bonded back to back, according to an embodiment.

FIG. 16 shows a cross-section of two example bonded substrates with TSVs and bonding pads, bonded front to front, according to an embodiment.

FIG. 17 shows a diagram of example TSVs used for heat management of a die, according to various embodiments.

FIG. 18 is a text flow diagram illustrating an example process of forming a microelectronic assembly to reduce or eliminate delamination of the bonded substrates, according to an embodiment.

### SUMMARY

Representative techniques and devices are disclosed, including process steps for preparing various microelectronic devices for bonding, such as for direct bonding without adhesive. In various embodiments, techniques may be employed to mitigate the potential for delamination due to metal expansion, particularly when a TSV or a bond pad over a TSV is presented at the bonding surface of one or both devices to be bonded. For example, in one embodiment, a metal pad having a larger diameter or surface area (e.g., oversized for the application) may be used when a contact pad is positioned over a TSV. For instance, the contact pad, including the size (e.g., surface area, diameter, etc.) of the contact pad, or the amount of oversize of the contact pad may be selected based on the material of the pad, its thickness, and anticipated recess during processing.

When using surface preparation processes such as CMP to prepare the bonding surface of the substrate, the metal pads on the bonding surface can become recessed relative to the dielectric, due to the softer material of the pads relative to the material of the dielectric. A larger diameter metal pad may become recessed to a greater degree (e.g., a deeper recess) than a smaller diameter pad. In an embodiment where a contact pad is positioned over a TSV, the deeper recess can compensate for a combined metal expansion of the pad and the TSV, allowing more room for expansion of the metal, which can reduce or eliminate delamination that could occur otherwise when the metal expands.

In various implementations, an example process includes embedding a first through silicon via (TSV) into a first substrate having a first bonding surface, where the first TSV is normal to the first bonding surface (i.e., vertical within a horizontally oriented substrate with a like horizontally oriented bonding surface. The process may include estimating an amount that a material of the first TSV will expand when heated to a preselected temperature, based on a volume of the material of the first TSV and a coefficient of thermal expansion (CTE) of the material of the first TSV. The process includes forming a first metal contact pad at the first bonding surface and coupled to the first TSV, based on the estimate or based on a volume of the material of the first TSV and a coefficient of thermal expansion (CTE) of the material of the first TSV.

The first metal contact pad is disposed at the first bonding surface (and may be disposed directly over the first TSV), and extends partially into the first substrate below the first bonding surface, electrically coupling the first metal contact pad to the first TSV. In the embodiment, the process includes planarizing the first bonding surface to have a predetermined maximum surface variance for direct bonding, and the first metal contact pad to have a predetermined recess relative to the first bonding surface, based on the volume of the material of the first TSV and the coefficient of thermal expansion (CTE) of the material of the first TSV.

In various examples, selecting or forming the contact pad comprises selecting a diameter or a surface area of the first metal contact pad. For instance, a first metal contact pad may be selected or formed to have an oversized diameter, an oversized surface area, or the like, than typical for a like application. In an embodiment, the process includes determining a desired recess for the first metal contact pad relative to the first bonding surface, to allow for expansion of the material of the first TSV and the material of the first metal contact pad, based on the predicting, and selecting the first metal contact pad to have a perimeter shape likely to result in the desired recess when the first metal contact pad is planarized. This may include forecasting an amount of recess that is likely to occur in a surface of the first metal contact pad as a result of the planarizing. In another embodiment, the process includes forming the desired recess in a surface of the first metal contact pad (prior to bonding), based on the determining.

In various embodiments, the process includes reducing or eliminating delamination of bonded microelectronic components by selecting the first metal contact pad. In an alternate implementation, the process includes recessing or eroding material of the first bonding surface directly around the first metal contact pad to allow for expansion of the material of the first TSV and the material of the first metal contact pad, based on the volume of the material of the first TSV and the coefficient of thermal expansion (CTE) of the material of the first TSV.

Additionally or alternatively, the back side of the first substrate may also be processed for bonding. One or more insulating layers of preselected materials may be deposited on the back side of the first substrate to provide stress relief when the back side of the first substrate is to be direct bonded.

Further, the first TSV, as well as other TSVs within the first substrate may be used to direct or transfer heat within the first substrate and/or away from the first substrate. In some implementations, the thermal transfer TSVs may extend partially or fully through a thickness of the first substrate and may include a thermally conductive barrier layer. In such examples, barrier layers normally used around the TSVs that tend to be thermally insulating may be replaced with thermally conductive layers instead. In various implementations, some TSVs may be used for signal transfer and thermal transfer.

In an embodiment, a microelectronic assembly comprises a first substrate including a first bonding surface with a planarized topography having a first predetermined maximum surface variance. A first through silicon via (TSV) is embedded into the first substrate and a first metal contact pad is disposed at the first bonding surface and is electrically coupled to the first TSV. The first contact pad may be disposed over the first TSV, for instance. The first metal contact pad may be selected or formed based on an estimate of an amount that a material of the first TSV will expand when heated to a preselected temperature and/or based on a volume of the material of the first TSV and a coefficient of thermal expansion (CTE) of the material of the first TSV. A predetermined recess is disposed in a surface of the first metal contact pad, having a volume equal to or greater than an amount of expansion of the material of the first TSV and an amount of expansion of a material of the first metal contact pad when heated to the preselected temperature.

In an implementation, the first metal contact pad is positioned over the first TSV and the first metal contact pad has an oversized diameter or an oversized surface area than a pad typically used for a like application.

Various implementations and arrangements are discussed with reference to electrical and electronics components and varied carriers. While specific components (i.e., dies, wafers, integrated circuit (IC) chip dies, substrates, etc.) are mentioned, this is not intended to be limiting, and is for ease of discussion and illustrative convenience. The techniques and devices discussed with reference to a wafer, die, substrate, or the like, are applicable to any type or number of electrical components, circuits (e.g., integrated circuits (IC), mixed circuits, ASICS, memory devices, processors, etc.), groups of components, packaged components, structures (e.g., wafers, panels, boards, PCBs, etc.), and the like, that may be coupled to interface with each other, with external circuits, systems, carriers, and the like. Each of these different components, circuits, groups, packages, structures, and the like, can be generically referred to as a “microelectronic component.” For simplicity, unless otherwise specified, components being bonded to another component will be referred to herein as a “die.”

This summary is not intended to give a full description. Implementations are explained in more detail below using a plurality of examples. Although various implementations and examples are discussed here and below, further implementations and examples may be possible by combining the features and elements of individual implementations and examples.

### DETAILED DESCRIPTION

### Overview

Referring to FIG. 1A (showing a cross-sectional profile view) and FIG. 1B (showing a top view), patterned metal and oxide layers are frequently provided on a die, wafer, or other substrate (hereinafter “die 102”) as a hybrid bonding, or DBI®, surface layer. A representative device die 102 may be formed using various techniques, to include a base substrate 104 and one or more insulating or dielectric layers 106. The base substrate 104 may be comprised of silicon, germanium, glass, quartz, a dielectric surface, direct or indirect gap semiconductor materials or layers or another suitable material. The insulating layer 106 is deposited or formed over the substrate 104, and may be comprised of an inorganic dielectric material layer such as oxide, nitride, oxynitride, oxycarbide, carbides, carbonitrides, diamond, diamond like materials, glasses, ceramics, glass-ceramics, and the like.

A bonding surface 108 of the device wafer 102 can include conductive features 110, such as traces, pads, and interconnect structures, for example, embedded into the insulating layer 106 and arranged so that the conductive features 110 from respective bonding surfaces 108 of opposing devices can be mated and joined during bonding, if desired. The joined conductive features 110 can form continuous conductive interconnects (for signals, power, etc.) between stacked devices.

Damascene processes (or the like) may be used to form the embedded conductive features 110 in the insulating layer 106. The conductive features 110 may be comprised of metals (e.g., copper, etc.) or other conductive materials, or combinations of materials, and include structures, traces, pads, patterns, and so forth. In some examples, a barrier layer may be deposited in the cavities for the conductive features 110 prior to depositing the material of the conductive features 110, such that the barrier layer is disposed between the conductive features 110 and the insulating layer 106. The barrier layer may be comprised of tantalum, for example, or another conductive material, to prevent or reduce diffusion of the material of the conductive features 110 into the insulating layer 106. After the conductive features 110 are formed, the exposed surface of the device wafer 102, including the insulating layer 106 and the conductive features 110 can be planarized (e.g., via CMP) to form a flat bonding surface 108.

Forming the bonding surface 108 includes finishing the surface 108 to meet dielectric roughness specifications and metallic layer (e.g., copper, etc.) recess specifications, to prepare the surface 108 for direct bonding. In other words, the bonding surface 108 is formed to be as flat and smooth as possible, with very minimal surface topology variance. Various conventional processes, such as chemical mechanical polishing (CMP), dry or wet etching, and so forth, may be used to achieve the low surface roughness. This process provides the flat, smooth surface 108 that results in a reliable bond.

In the case of double-sided dies 102, a patterned metal and insulating layer 106 with prepared bonding surfaces 108 may be provided on both sides of the die 102. The insulating layer 106 is typically highly planar (usually to nm-level roughness) with the metal layer (e.g., embedded conductive features) at or recessed just below the bonding surface 108. The amount of recess below the surface 108 of the insulating layer 106 is typically determined by a dimensional tolerance, specification, or physical limitation. The bonding surfaces 108 are often prepared for direct bonding with another die, wafer, or other substrate using a chemical-mechanical polishing (CMP) step and/or other preparation steps.

Some embedded conductive features or interconnect structures may comprise metal pads 110 or conductive traces 112 that extend partially into the dielectric substrate 106 below the prepared surface 108. For instance, some patterned metal (e.g., copper) features 110 or 112 may be about 0.5-2 microns thick. The metal of these features 110 or 112 may expand as the metal is heated during annealing. Other conductive interconnect structures may comprise metal (e.g., copper) through silicon vias (TSVs) 114 or the like, that extend normal to the bonding surface 108, partly or fully through the substrate 102 and include a larger quantity of metal. For instance, a TSV 114 may extend about 50 microns, depending on the thickness of the substrate 102. The metal of the TSV 114 may also expand when heated. Pads 110 and/or traces 112 may or may not be electrically coupled to TSVs 114, as shown in FIG. 1A.

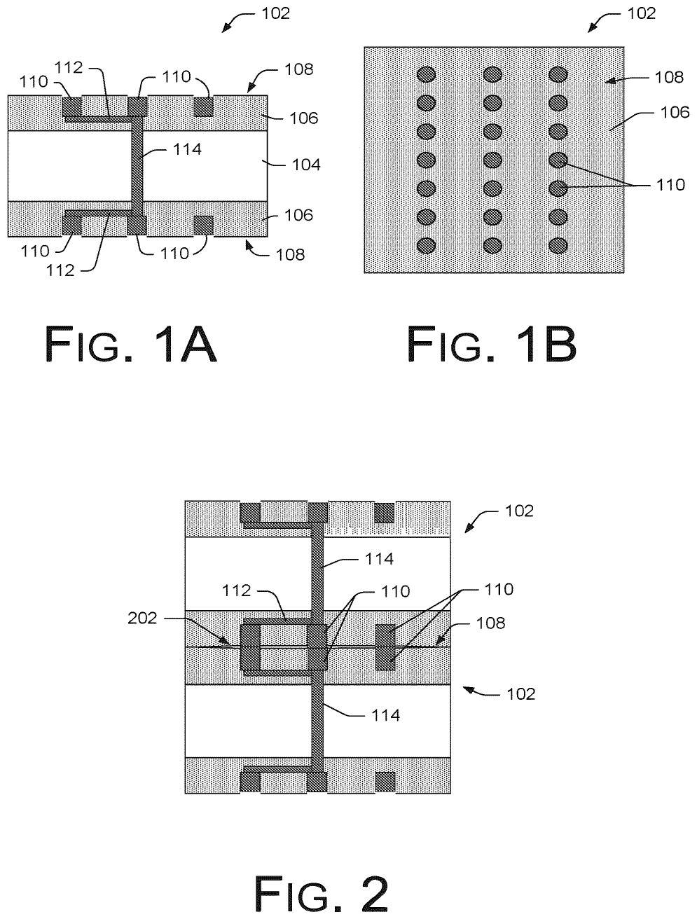

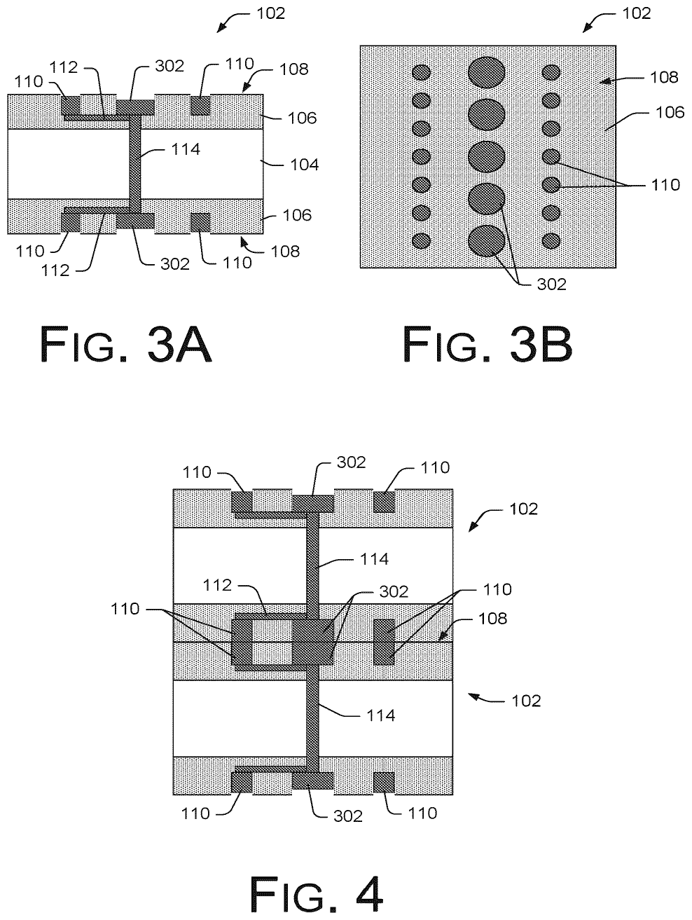

Referring to FIG. 2, dies 102 may be direct bonded, for instance, without adhesive to other dies 102 with metal pads 110, traces 112, and/or TSVs 114. If a metal pad 110 is positioned over a TSV 114 (electrically coupled to the TSV 114), the expansion of the TSV 114 metal can contribute to the expansion of the pad 110 metal. In some cases, the combined metal expansion can cause localized delamination 202 of the bonding surfaces at the location of the TSV 114 (or TSV 114/pad 110 combination), as the expanding metal rises above the bonding surface 108. For instance, the expanded metal can separate the bonded dielectric surfaces 108 of the stacked dies 102.

### EXAMPLE EMBODIMENTS

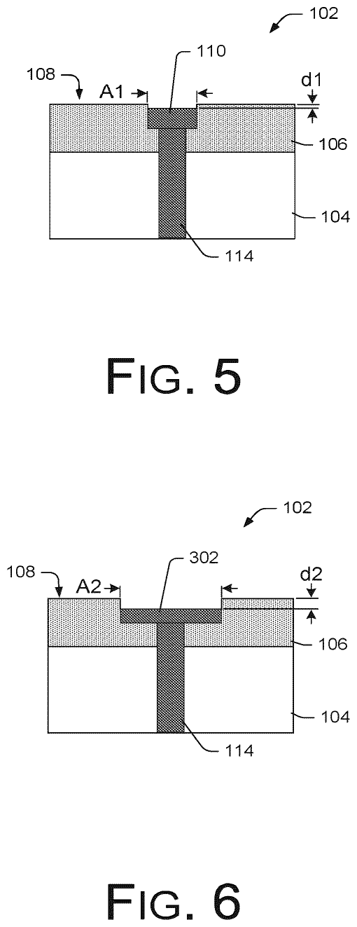

Referring to FIGS. 3A, 3B, and 4, in various embodiments, techniques may be employed to mitigate the potential for delamination due to metal expansion. For example, in one embodiment, a metal pad 302 having a larger diameter or surface area (e.g., oversized for the application) may be used in place of a contact pad 110 when positioned over a TSV 114. For instance, the pad 302 may have a larger diameter than other contact pads 110 at the surface 108 of the die 102, so that the pad 302 will have a deeper recess for a given CMP process than the other contact pads 110 that are not positioned over a TSV 114. Similar to the contact pads 110, the contact pad 302 may be embedded in the dielectric layer 106, extending partially into the dielectric layer 106 below the bonding surface 106, and electrically coupled to the TSV 114. For instance, the amount of oversize of the metal pad 302 may be selected based on the material of the pad 302, its thickness, and anticipated recess during CMP processing.

As shown in FIG. 3A (showing a cross-sectional profile view) and FIG. 3B (showing a top view), pads 302 disposed over TSVs 114 may be larger (in area, diameter, etc.), by a preselected amount, than other pads 110 disposed elsewhere at the bonding surface 108 of the die 102 (e.g., not disposed over TSVs 114). In an embodiment, the pads 302 are selected or formed by estimating an amount that the material of the TSV 114 will expand when heated to a preselected temperature)(˜300°, based on a volume of the material of the TSV 114 and a coefficient of thermal expansion (CTE) of the material of the TSV 114, and predicting an amount that the material of the contact pad 302 will expand when heated to the preselected temperature, based on a volume of the material of the contact pad 302 and a CTE of the material of the contact pad.

The contact pad 302 is planarized along with the bonding surface 108 of the dielectric layer 106, including recessing the contact pad 302 to have a predetermined recess depth (or amount) relative to the bonding surface 108 based on estimating and predicting the expansion of the TSV 114 material and the contact pad 302 material at the preselected temperature.

Referring to FIG. 4, after preparation of the bonding surface 108 (e.g., by CMP) the dies 102 may be direct bonded, for instance, without adhesive to other dies 102 with metal pads 110 and/or 302, traces 112, and/or TSVs 114. When a metal pad 302 is positioned over a TSV 114, and is recessed a predetermined or predictable amount, the recess provides room for material expansion without delamination. The TSV 114 material and the pad 302 material expand during heated annealing. The mating contact pads 302 (or 302 and 110 in some examples) of opposite dies 102 bond to form a single conductive interconnect. However, the combined metal expansion does not cause delamination of the bonding surfaces since the expanding metal does not exceed the volume formed by the recess(es) in the contact pads 302 (or 302 and 110 in some examples). For instance, if the volume of the recess(es) is sufficient, the expanded metal does not separate the bonded dielectric surfaces 108 of the stacked dies 102, as shown in FIG. 4.

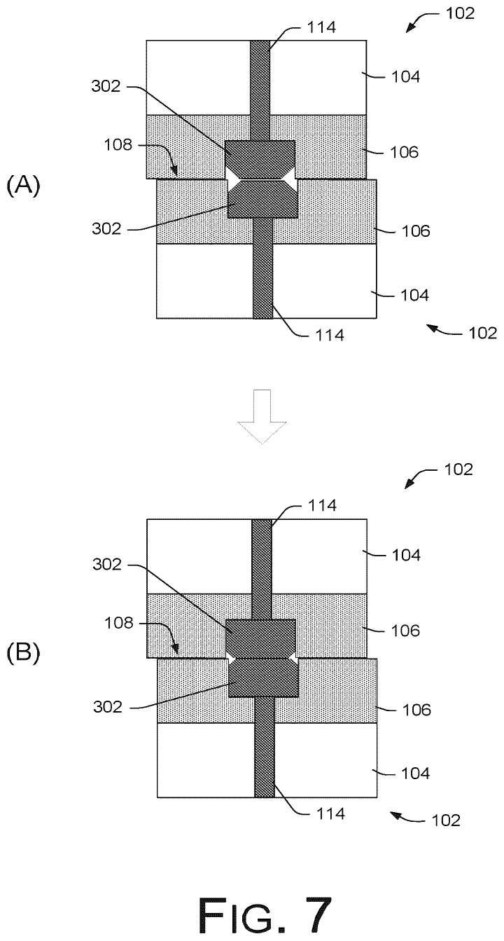

Referring to FIGS. 5 and 6, details of contact pads 110 and 302 over TSVs 114 are illustrated. A portion of a die 102 is shown, first with a contact pad 110 over a TSV 114 (FIG. 5) and then with a contact pad 302 over a TSV 114 (FIG. 6). When using surface preparation processes such as CMP to prepare the bonding surface 108 of the die 102, the metal pads 110 or 302 on the bonding surface 108 can tend to become recessed relative to the dielectric 106, due to the softness of the contact pads 110 or 302 (which may comprise copper, for instance) relative to the dielectric 106 (which may comprise an oxide, for example).

In various embodiments, a contact pad 302 with a larger diameter or surface area A2 than a contact pad 110 with a smaller diameter or surface area A1 (shown at FIGS. 5 and 6, where A2>A1) may become recessed to a greater degree “d2” (e.g., a deeper recess) than the recess “d1” of the smaller diameter pad 110 during a similar CMP process. The deeper recess “d2” can compensate for the combined metal expansion of the pad 302 and the TSV 114, allowing more room for expansion of the metal, and can reduce or eliminate delamination. In some embodiments, the contact pad 302 may be intentionally recessed to the desired depth “d2” and in other embodiments, the contact pad 302 may be selected due to the predictable recess “d2” that results from surface 108 preparation by CMP (or other processing), based on the size (diameter and/or surface area), material composition, etc. of the pad 302.

In various embodiments, the amount of recessing (e.g., d1, d2, etc.) of a metal pad 110 or 302 may be predictable, based on the surface preparation technique used (e.g., the chemical combination used, the speed of the polishing equipment, etc.), the materials of the dielectric layer 106 and the metal pads 110 and 302, the spacing or density of the metal pads 110 and 302, and the size (e.g., area or diameter) of the metal pads 110 and 302. In the embodiments, the area or diameter of the metal pads 110 and 302 may be selected (e.g., for a particular metal thickness) to avoid delamination of bonded dies 102 based on the recess prediction and the expected metal expansion of the TSV 114 and metal pad 110 or 302 combination. For example, larger sized pads 302 may be used over TSVs 114 and smaller sized pads 110 may be used over dielectric 106 (to avoid excessive recessing of these pads 110). This technique can result in reduced or eliminated delamination, as well as dependable mechanical coupling of the dielectric 106 and metal structures (110, 302, 112, and/or 114) on the bonding surfaces 108 and reliable electrical continuity of the bonded metal structures (110, 302, 112, and/or 114).

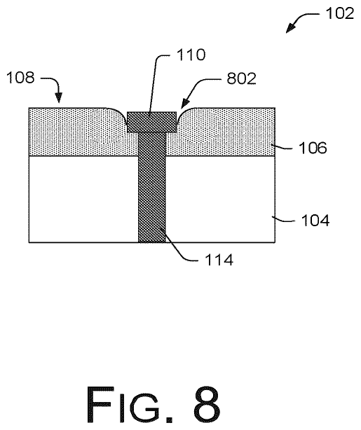

In one embodiment, a metal pad 110, 302 may be selectively etched (via acid etching, plasma oxidation, etc.) to provide a desired recess depth (to accommodate a predicted metal expansion). In another embodiment, a pad 110, 302 or a corresponding TSV 114 may be selected, formed, or processed to have an uneven top surface as an expansion buffer. For example, referring to FIG. 7, the top surface of the pad 302 (or TSV 114 in some cases) may be formed or selectively etched to be rounded, domed, convex, concave, irregular, or otherwise non-flat to allow room for material expansion.

As shown at FIG. 7 at A, the top or bonding surface of the contact pads 302 are selected, formed, or processed to have an uneven surface. As shown at B, after material expansion due to heated annealing, the pads 302 make contact and are bonded. However, with an adequate space for expansion provided by the uneven top surfaces of the pads 302, the material does not exceed the space provided, and so delamination of the bonded dies 102 does not occur.

Additionally or alternately, as shown in FIG. 8, the dielectric 106 around the metal pad 110 or 302 can be formed or shaped to allow room for the metal of the pad 110 or 302 (and TSV 114) to expand. In one example, a CMP process can be used to shape the surface 108 of the dielectric 106 around the metal pad 302, or in other examples other processes can be used, so that the dielectric 106 around the pad 302 includes a recess 802 or other gap that provides room for metal expansion.

In an embodiment, the dielectric 106 can be recessed (e.g., with CMP) while the bonding surface 108 is being prepared. In the embodiment, the metal pad 110 or 302 and the dielectric 106 may be recessed concurrently (but at different rates). For instance, the process may form erosion 802 in the dielectric 106 around the edges of the metal pad 110 or 302 while recessing the metal pad 110 or 302.

In various embodiments, the pad 110 or 302 and/or the TSV 114 are comprised of copper, a copper alloy, or the like. In a further embodiment, the materials of the pad 110 or 302 and/or the TSV 114 may be varied to control metal expansion and potential resulting delamination. For instance, in some embodiments, the pad 110 or 302 and/or the TSV 114 may be comprised of different conductive materials, perhaps with lower CTEs. In some embodiments the TSV 114 may be comprised of a different conductive material (with a lower CTE) than the contact pad 110 or 302. For example, the TSV 114 may be comprised of tungsten, an alloy, or the like.

In other embodiments the volume of material of the TSV 114 may be varied to control metal expansion and the potential for resulting delamination. For instance, in some embodiments, a TSV 114 with a preselected material volume (e.g., less volume of material) may be used to control delamination, when this is allowable within the design specifications. The preselection of volume of the TSV 114 may be based on predicted material expansion (of the TSV 114 and a contact pad 110 or 302, when applicable).

In an alternate embodiment, the metal contact pad 110 or 302 may be offset or relocated from the TSV 114, rather than being positioned directly over the TSV 114. For instance, the metal pad 110 or 302 may be positioned so that it is not directly over the TSV 114, and be coupled to the TSV 114 by a metal trace 112, or the like, if desired. If the contact pad 110 or 302 is offset from the TSV 114, a cavity may be created to allow the TSV 114 to expand in the z-direction without affecting the bond interface. The cavity may be left open or may be filled with a material, such as a compliant material.

Alternately, the top surface of the TSV 114 can be arranged to be exposed at the bonding surface 108 and used as a contact pad. These arrangements can avoid combining the expansion of the metal pad 110 or 302 with that of the TSV 114, and so minimizing or eliminating delamination.

In a further embodiment, the TSV 114 can be formed so that the TSV 114 extends partially (rather than fully) through the thickness of the substrate 102, terminating below the bonding surface 108. A gap or recess can be provided in the bonding surface 108 over the TSV 114 to allow room for the metal of the TSV 114 to expand, without causing delamination. For instance, the gap can be formed by etching the dialectic layer 106. The gap may or may not expose the TSV 114. The gap can be tuned, for example, to the volume of the TSV 114, using a prediction of the expansion of the TSV 114, based on the volume of the particular metal of the TSV 114.

### Additional Embodiments

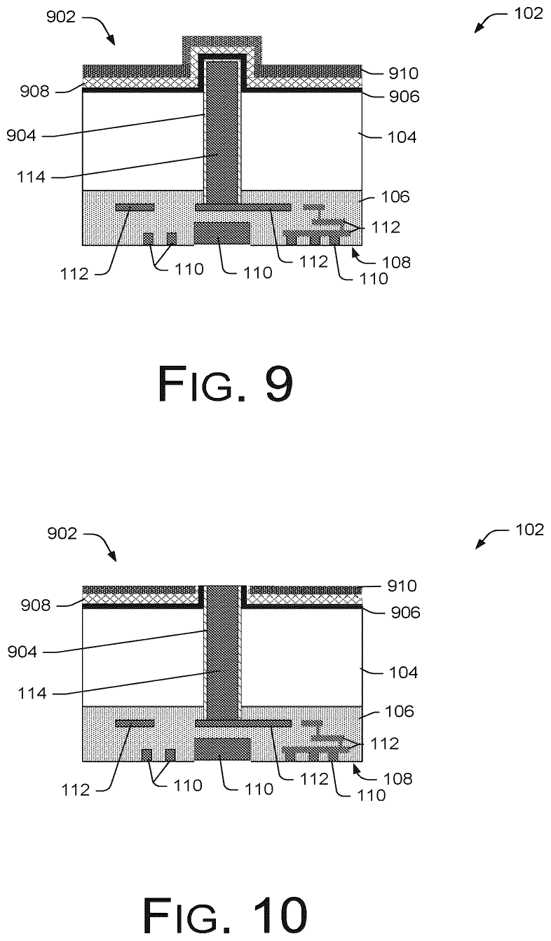

FIGS. 9-13 illustrate examples of backside die 102 processing, according to various embodiments. In some implementations, where dies 102 are stacked and direct bonded without adhesive, the backside 902 of the die 102 may receive different preparation than the topside bonding surface 108, when the backside 902 is prepared for direct bonding. Instead of forming the dielectric layer 106 on the backside 902 of the die 102, the backside 902 may be prepared differently to reduce process steps, reduce manufacturing costs, or for other reasons.

In one implementation, the backside 902 is prepared so that the backend of the TSV 114 is exposed, to be used as a contact surface for bonding to a conductive pad, interconnect, or other conductive bonding surface. The preparation may include thinning and selectively etching the base substrate 104 to expose the TSV 114 with the liner/barrier layer 904 intact, depositing one or more layers of insulating materials and planarizing (via CMP, for example) the backside 902 to reveal the TSV 114. In some cases, however, the expansion of the material of the TSV 114 during heated annealing can cause the insulating material and/or the substrate 104 to deform and rise above the planarized surface.

In an embodiment, as shown in FIGS. 9-13, one or more layers of material may be deposited on the backside 902 to cover up the raised area so the new surface can be re-planarized for good dielectric-to-dielectric bonding. Another important function of the multi-layer structure is to balance the stress between the front and back side of the die 102 to minimize die warpage prior to bonding. A balanced die 102 is easier to bond and less prone to bonding voids. The added layers of material can be planarized and otherwise prepared as a bonding surface on the backside 902 of the die 102.

As shown at FIG. 9, the TSV 114 is disposed within the die 102, transverse to the bonding surface 108 of the die 102. The TSV 114 may extend beyond the surface of the base substrate 104 after selective etching of the base substrate 104. A diffusion barrier and oxide liner 904 surrounds the TSV 114 to prevent diffusion of the metal of the TSV 114 (e.g., copper) into the material of the base substrate 104 (e.g., silicon). In an embodiment, as shown at FIG. 9, another diffusion barrier 906 is deposited on the surface of the backside of the die 102. In an example, the diffusion barrier 906 comprises a dielectric, such as a nitride or the like.

In various embodiments, one or more inorganic dielectric layers which may have different residue stress characteristics are then deposited onto the backside 902 of the die 102 to enable proper reveal of the TSV 114 and to balance stress on the device side (front side) of the die 102 to minimize die warpage after singulation. For example, a first layer 908, comprising a first low temperature dielectric, such as an oxide, may be deposited over the backside 902, including the diffusion layer 906.

In some embodiments, a second layer 910, comprising a second low temperature dielectric, such as a second oxide, may be deposited over the backside 902, including the first layer 908. The second oxide layer 910 may have a similar or a different residue stress characteristic than the first layer 908 (for example, the first layer 908 may be compressive and the second layer 910 may be tensile, or vice versa, or both layers 908 and 910 may be compressive or tensile with similar or different values). In various implementations, the first layer 908 and the second 910 layer are comprised of similar or the same materials (in varying thicknesses). In other implementations, the first layer 908 and the second 910 layer are comprised of different materials. In alternate implementations, additional dielectric layers may also be deposited over the first 908 and second 910 layers.

As shown at FIG. 10, the backside 902 is planarized (via CMP, for example), including the one or more stress layers 908 and 910 to form a flat, smooth bonding surface for direct bonding. Part of the second layer 910 may be left on the backside 902 to aid with mitigating damage, such as the oxide ring effect. Additionally, the remaining portion of the second layer 910 can assist with warpage control, based on a residue stress characteristic of the second layer 910.

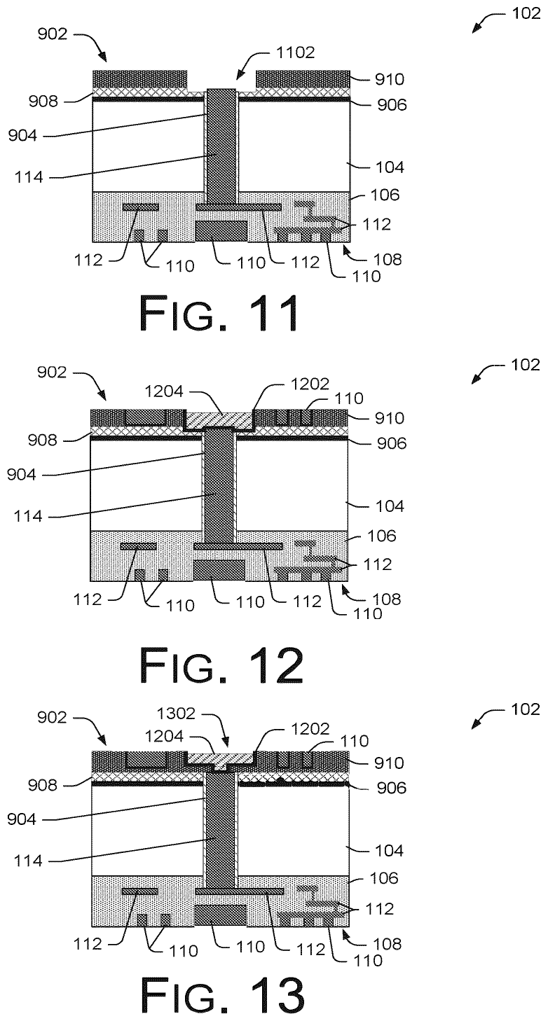

In another embodiment, as shown in FIGS. 11-12, a contact pad 1204 may be coupled to the TSV 114 on the backside 902 of the die 102. As shown at FIG. 11, after deposition of the first dielectric layer (low temperature oxide stress layer 908, for example), which also comprises the bonding layer in some implementations, the TSV 114 is fully exposed and planarized by a process such as CMP. A second dielectric layer 910 (which may comprise an oxide) may be deposited over the first layer 908 and planarized. No barrier or adhesion layer is needed between the two oxide layers (908 and 910). After planarization, the backside 902 is patterned and opened (e.g., etched, etc.) for deposition of a conductive pad. As shown in FIG. 11, the opening 1102 in the oxide layers 908 and 910 may have a larger diameter than that of the TSV 114.

In an embodiment, the opening 1102 for the contact pad 1204 extends through the second layer 910 and partially (10-1000 nm) into the first layer 908. A barrier/adhesion layer 1202 (comprising titanium/titanium nitride, tantalum/tantalum nitride, etc.) may be deposited into the opening 1102 (and may cover the entire surface of the opening 1102), as shown at FIG. 12. A copper (or the like) deposition/plating (e.g., damascene process) fills the opening 1102, which is planarized (via CMP, for example) to remove excess copper and to set the resulting contact pad 1204 recess to a specified depth. The backside 902 surface is prepared for bonding at this point.

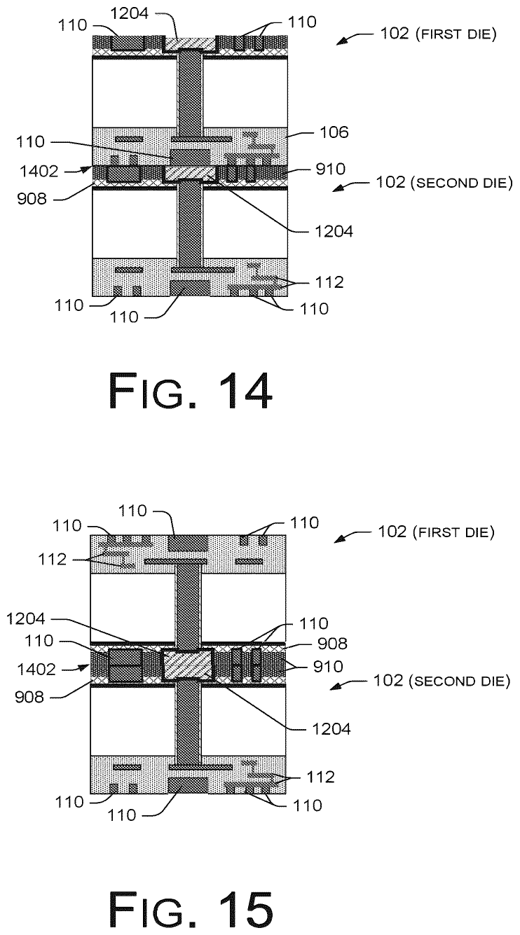

In an alternate embodiment, a dual damascene process may be used to form the contact pad 1204, as shown in FIG. 13. In the embodiment, after depositing the second dielectric layer 910 (which may comprise an oxide) onto the first layer 908 (with no barrier or adhesion layer), the resulting backside 902 surface is patterned twice to form a unique opening 1302 for the contact pad 1204 in a dual damascene process. A first a small opening, with a diameter smaller than the diameter of the TSV 114 is etched partially through the layer 908, then a large opening (larger diameter than the diameter of the TSV 114) over the small opening is patterned and etched, resulting in a smaller opening extending to the TSV 114 and a larger opening partially through layer 910. For instance, in some cases, design rules dictate the presence of a via layer.

A thickness of the second dielectric layer 910 (top layer) and a thickness of the contact pad 1204 may be adjusted to minimize thin die warpage, and to achieve a desired anneal temperature. In other embodiments, alternate techniques may be used to reduce or eliminate delamination due to metal feature expansion, and remain within the scope of the disclosure.

FIGS. 14-16 show example stacking arrangements of the dies 102 formed with regard to FIGS. 9-13 (and like structures) with front side 108 and backside 902 interconnectivity. For example, at FIG. 14, an example “front-to-back” die 102 stack arrangement is shown. This bonds a front side bonding surface 108 of a first die 102 to a backside 902 bonding surface of a second die 102, including a contact pad 110 or 302 of the first die 102 to a contact pad 1204 of the second die 102. In an example, as discussed above, the contact pad 1204 of the second die 102 penetrates into the second dielectric layer 910 and the first dielectric layer 908 of the second die 102, below the bonding interface 1402.

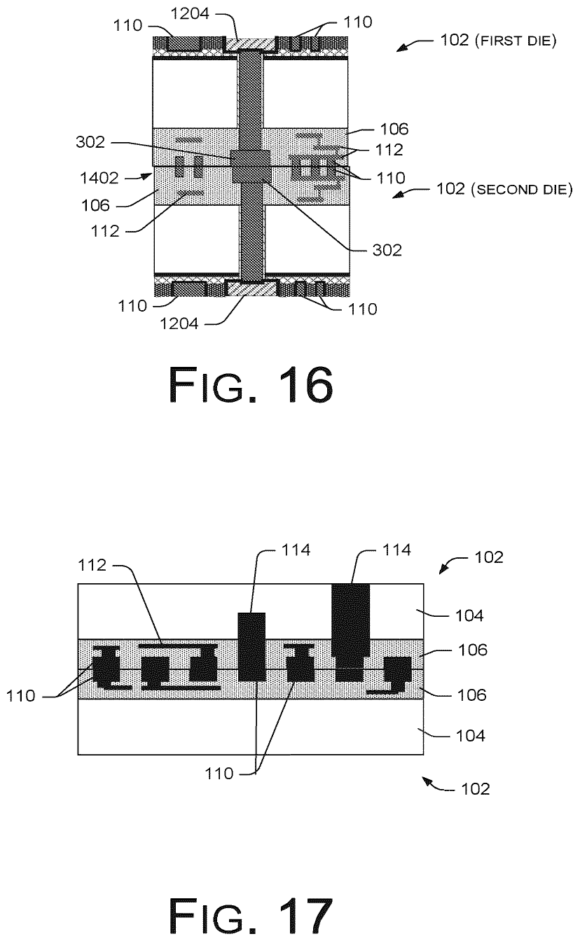

At FIG. 15, an example “back-to-back” die 102 stack arrangement is shown. This bonds a backside 902 bonding surface of a first die 102 to a backside 902 bonding surface of a second die 102, including a contact pad 1204 of the first die 102 to a contact pad 1204 of the second die 102. In an example, as discussed above, the contact pads 1204 of the first and second dies 102 penetrate into the second dielectric layer 910 and the first dielectric layer 908 of the first and second dies 102, below the bonding interface 1402.

At FIG. 16, an example “front-to-front” die 102 stack arrangement is shown. This bonds a front side bonding surface 108 of a first die 102 to a front side bonding surface 108 of a second die 102 at the bonding interface 1402, including a contact pad 110 or 302 of the first die 102 to a contact pad 110 or 302 of the second die 102. In the example shown, the contact pads 110 or 302 are electrically coupled to the TSVs 114 of the respective dies 102.

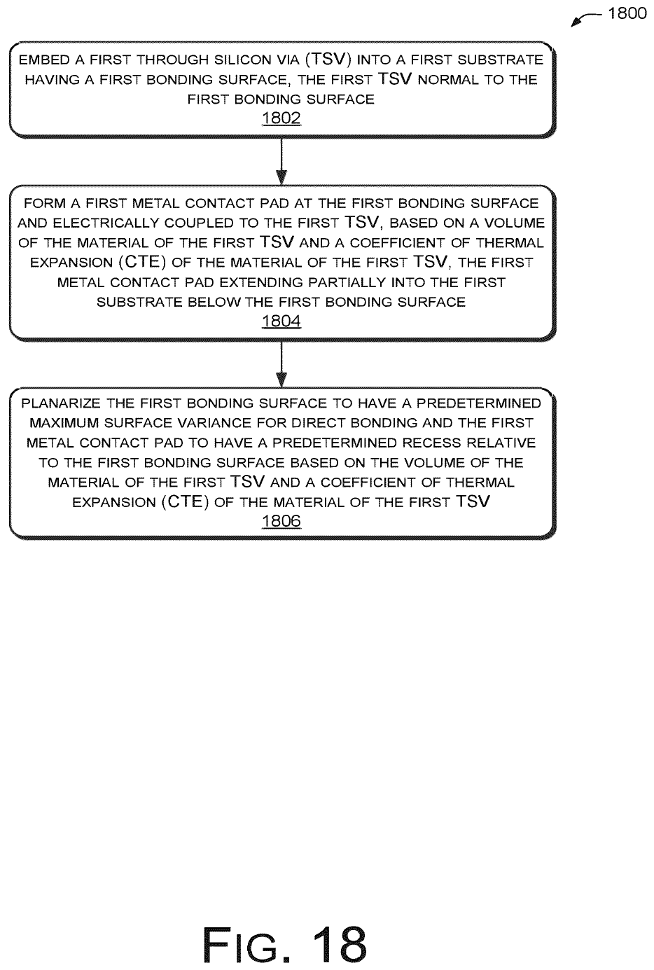

In various embodiments, as illustrated at FIG. 17, one or more of the TSVs 114 of a set of stacked dies 102 may be used to conduct heat in addition to or instead of electrical signals. For example, in some cases, it may not be practical or possible to attach a heat sink (or other heat transfer device) to a die 102 of a set of stacked dies 102 to alleviate heat generated by the die 102. In such cases, other techniques may be looked—for to transfer heat as desired.

In the embodiments, as shown at FIG. 17, various configurations of TSVs 114, including TSVs that extend partially or fully through a die 102, may be employed to conduct heat away from the dies 102 (or away from a heat-generating portion of the dies 102). The TSVs 114 of one die 102 may be used in conjunction with TSVs 114, contact pads 110 and 302, traces 112, and the like, of the second die 102 to complete heat transfer from one die 102 to the other die 102, and so forth. The TSVs 114 of the first die 102 can be direct bonded (e.g., DBI) to the TSVs 114, contact pads 110 and 302, traces 112, and the like of the second die 102 for high performance thermal conductivity.

In an implementation, some of the TSVs 114, contact pads 110 and 302, traces 112, and the like are electrically floating or “dummy” structures, which can be used for thermal transfer. These structures may conduct heat away from a high power die 102 to another die 102 or substrate as desired. Dummy contact pads 110 or 302 may be coupled to via last or via mid thermal TSVs 114 for thermal conduction.

In the embodiments, diffusion barrier/oxide liner layers 904, which surround the TSVs 114 and can be thermally restrictive or thermal barriers may be replaced by diffusion barrier/oxide liners of a different material having some thermal conductivity (such as metal or alloy barriers, or the like).

### Example Process

FIG. 18 illustrates a representative process 1800 for preparing various microelectronic components (such as dies 102, for example) for bonding, such as for direct bonding without adhesive, while reducing or eliminating the potential for delamination due to metal expansion of embedded structures at the bonding surface. For instance, through-silicon vias (TSVs) at the bonding surface may cause delamination, particularly when coupled to contact pads, as the material of the TSVs and the contact pads expands during heated annealing. The process refers to FIGS. 1-18.

The order in which the process is described is not intended to be construed as limiting, and any number of the described process blocks in the process can be combined in any order to implement the process, or alternate processes. Additionally, individual blocks may be deleted from the process without departing from the spirit and scope of the subject matter described herein. Furthermore, the process can be implemented in any suitable hardware, software, firmware, or a combination thereof, without departing from the scope of the subject matter described herein. In alternate implementations, other techniques may be included in the process in various combinations and remain within the scope of the disclosure.

In an implementation, a die, wafer, or other substrate (a “substrate”) is formed using various techniques to include a base substrate and one or more dielectric layers. In the implementation, at block 1802, the process 1800 includes embedding a first through silicon via (TSV) (such as TSV 114, for example) into a first substrate (such as die 102, for example) having a first bonding surface (such as bonding surface 108, for example), the first TSV normal to the first bonding surface.

In the implementation, at block 1804, the process includes forming a first metal contact pad (such as contact pad 302, for example) at the first bonding surface and electrically coupled to the first TSV, based on a volume of the material of the first TSV and a coefficient of thermal expansion (CTE) of the material of the first TSV. In an embodiment, the first metal contact pad extends partially into the first substrate below the first bonding surface.

At block 1806, the process includes planarizing the first bonding surface to have a predetermined maximum surface variance for direct bonding and the first metal contact pad to have a predetermined recess relative to the first bonding surface based on the volume of the material of the first TSV and the coefficient of thermal expansion (CTE) of the material of the first TSV. In an implementation, the process includes predicting an amount that a material of the first metal contact pad will expand when heated to a preselected temperature, based on a volume of the material of the first metal contact pad and a CTE of the material of the first metal contact pad, and determining a size of the first metal contact pad based on the estimating combined with the predicting. In one implementation, the process includes selecting a diameter or a surface area of the first metal contact pad.

In an implementation, the process includes electrically coupling the first metal contact pad to the first TSV.

In an implementation, the process includes determining a desired recess for the first metal contact pad relative to the first bonding surface, to allow for expansion of the material of the first TSV and the material of the first metal contact pad, based on the estimating and the predicting; and selecting the first metal contact pad to have a perimeter shape likely to result in the desired recess when the first metal contact pad is planarized.

In another implementation, the process includes determining a desired recess for the first metal contact pad relative to the first bonding surface, to allow for expansion of the material of the first TSV and the material of the first metal contact pad based on the predicting; and forming the desired recess in a surface of the first metal contact pad.

In another implementation, the process includes selecting the first metal contact pad to have an oversized diameter or an oversized surface area than typical for a like application.

In a further implementation, the process includes forecasting an amount of recess that is likely to occur in a surface of the first metal contact pad as a result of the planarizing. In another implementation, the process includes recessing or eroding material of the first bonding surface directly around the first metal contact pad to allow for expansion of the material of the first TSV and a material of the first metal contact pad, based on the estimating.

In an implementation, the process includes reducing or eliminating delamination of bonded microelectronic components by offsetting a position of the first metal contact pad relative to the first TSV so that the first metal contact pad is not disposed directly over the first TSV. In another implementation, the process includes forming a recess in the first bonding surface over the first TSV to allow for expansion of the material of the first TSV. In another implementation, the process includes tuning a volume of the recess in the first bonding surface based on the estimating.

In an implementation, the process includes reducing or eliminating delamination of bonded microelectronic components by extending the first TSV to the first bonding surface and using a top surface of the first TSV as a contact pad at the first bonding surface.

In various embodiments, some process steps may be modified or eliminated, in comparison to the process steps described herein.

The techniques, components, and devices described herein are not limited to the illustrations of FIGS. 1-18, and may be applied to other designs, types, arrangements, and constructions including with other electrical components without departing from the scope of the disclosure. In some cases, additional or alternative components, techniques, sequences, or processes may be used to implement the techniques described herein. Further, the components and/or techniques may be arranged and/or combined in various combinations, while resulting in similar or approximately identical results.

### CONCLUSION

Although the implementations of the disclosure have been described in language specific to structural features and/or methodological acts, it is to be understood that the implementations are not necessarily limited to the specific features or acts described. Rather, the specific features and acts are disclosed as representative forms of implementing example devices and techniques.

What is claimed is:

1. A method of forming a microelectronic assembly, comprising:
providing a first through substrate via (TSV) in a first substrate having a first surface;
forming a first metal contact pad in the first surface electrically coupled to and aligned over the first TSV;
forming a second metal contact pad in the first surface, the second metal contact pad having no TSV aligned thereunder, wherein the second metal contact pad has a different structure from the first metal contact pad to allow greater expansion of the TSV and first metal contact pad relative to the second metal contact pad; and
treating the first surface, the first metal contact pad and the second metal contact pad to form a first bonding surface for direct hybrid bonding.

2. The method of claim 1, wherein the second metal contact pad is thicker in a dimension normal to the first bonding surface than the first metal contact pad.

3. The method of claim 2, wherein the second metal contact pad has a smaller surface area at the first bonding surface than the first metal contact pad.

4. The method of claim 2, wherein treating the first surface, the first metal contact pad and the second metal contact pad to form the first bonding surface for direct hybrid bonding comprises chemical mechanical planarization.

5. The method of claim 1, wherein treating the first surface, the first metal contact pad and the second metal contact pad to form the first bonding surface for hybrid direct bonding comprises recessing the first metal contact pad from a dielectric surface of the first bonding surface to a greater degree than recessing the second metal contact pad from the dielectric surface to leave the second metal contact pad thicker than the first metal contact pad.

6. The method of claim 5, wherein recessing the first metal contact pad from the first surface to a greater degree than recessing the second metal contact pad from the first surface comprises chemical mechanical planarization.

7. The method of claim 1, wherein the first metal contact pad has an uneven top surface to provide greater volume for thermal expansion relative to the second metal contact pad.

8. The method of claim 1, further comprising:
providing a second substrate having a second bonding surface including a plurality of conductive interconnects;
direct hybrid bonding the first bonding surface of the first substrate to the second bonding surface of the second substrate without intervening adhesive, including directly bonding the first metal contact pad and the second metal contact pad to corresponding conductive interconnects of the second substrate.

9. The method of claim 8, wherein direct hybrid bonding comprising heating the first and second substrates to expand the first metal contact pad and the second metal contact pad into electrical and physical contact with the corresponding conductive interconnects of the second substrate.

10. A microelectronic assembly, comprising:
a first substrate comprising a first through substrate via (TSV) and a first bonding surface configured for direct hybrid bonding;
a first metal contact pad at the first bonding surface, the first metal contact pad aligned with and in electrical contact with the first TSV; and
a second metal contact pad at the first bonding surface, the second metal contact pad not aligned with any TSV in the first substrate, wherein the first metal contact pad is thinner in a dimension normal to the first bonding surface compared to the second metal contact pad.

11. The microelectronic assembly of claim 10, wherein the first metal contact pad is positioned directly over the first TSV.

12. The microelectronic assembly of claim 10, wherein the first metal contact pad has a larger surface area than the second metal contact pad.

13. The microelectronic assembly of claim 12, wherein:
the first metal contact pad is recessed by a first recess depth from an upper insulating surface of the first bonding surface;
the second metal contact pad is recessed by a second recess depth from the upper insulating surface of the first bonding surface; and
the first recess depth is greater than the second recess depth.

14. The microelectronic assembly of claim 13, where the first substrate includes a second bonding surface on a side opposite the first bonding surface.

15. The microelectronic assembly of claim 10, wherein the first substrate is direct hybrid bonded to a second substrate at the first bonding surface of the first substrate.

16. A microelectronic assembly, comprising:
a first substrate comprising a first bonding surface, the first substrate comprising
a first through substrate via (TSV),
a first metal contact pad at the first bonding surface, the first metal contact pad aligned with and in electrical contact with the first TSV, and
a second metal contact pad at the first bonding surface, the second metal contact pad without a corresponding TSV in the first substrate, wherein the first metal contact pad is thinner in a dimension normal to the first bonding surface than a thickness of the second metal contact pad; and
a second substrate comprising a second bonding surface, the second substrate comprising
a third metal contact pad at the second bonding surface, and
a fourth metal contact pad at the second bonding surface;
wherein the first bonding surface is direct hybrid bonded to the second bonding surface such that the first metal contact pad is directly bonded to the third metal contact pad and the second metal contact pad is directly bonded to the fourth metal contact pad.

17. The microelectronic assembly of claim 16, wherein the first substrate includes an additional bonding surface on a side opposite the first bonding surface.

18. The microelectronic assembly of claim 17, wherein the additional bonding surface is defined by an inorganic dielectric layer and a plurality of additional metal contact pads.

19. The microelectronic assembly of claim 16, wherein:
the second substrate comprises a second TSV aligned with and electrically connected to the third metal contact pad; and
the third metal contact pad is thinner in the dimension normal to the first bonding surface than a thickness of the fourth metal contact pad.

20. The microelectronic assembly of claim 16, wherein the first metal contact pad has a larger surface area than the second metal contact pad.
